(19) United States
(12) Patent Application Publication
(10) Pub. No.: US 2026/0244815 A1
(43) Pub. Date: Aug. 20, 2026

(54) TRAINED MODEL, TRAFFIC CONDITION ESTIMATION DEVICE, AND PROGRAM

(71) Applicant: NTT, Inc., Tokyo (JP)

(72) Inventors: Yoshie MORITA, Tokyo (JP); Yoichi MATSUO, Tokyo (JP); Kengo TAJIRI, Tokyo (JP)

(21) Appl. No.: 19/164,780

(22) PCT Filed: Feb. 20, 2024
(86) PCT No.: PCT/JP2024/006076

§ 371 Date: Sep. 12, 2025

(30) Foreign Application Priority Data
Mar. 29, 2023 (WO) PCT/JP2023/012929

(51) Int. Cl. G06F 30/18; G08G 1/052

(52) U.S. Cl. CPC G06F 30/18; G08G 1/052

(57) ABSTRACT

A traffic state estimation device configured to estimate traffic states of roads includes a trained model configured to estimate one or more distributions of first traffic parameters indicating values of components of the traffic states, based on first road information that is physical information of the roads, and to output the distributions. The traffic state estimation device includes circuitry configured to input, to the trained model, second road information related to a predetermined road such that the trained model outputs a first distribution of second traffic parameters in association with the second road information, and to derive an estimate value regarding the second traffic parameters, based on the first distribution of the second traffic parameters output from the trained model.

### TECHNICAL FIELD

The present disclosure relates to a technique for estimating traffic density, traffic volume, and travel speed of a road.

### BACKGROUND ART

Traffic volume, travel speed, and traffic density are important factors in road design, determination of a speed limit, and the like. The traffic volume is also represented as a product of the travel speed and the traffic density, and these three elements are in a relationship in which one can be determined if two are determined. Hereinafter, the traffic volume, the travel speed, and the traffic density are collectively referred to as “traffic state”.

In the road design and the like, a maximum value, an average value, and the like of the traffic state are required. For example, the maximum value of the traffic volume is required to confirm whether a reference traffic capacity of the road is exceeded, or the average value of the travel speed is required to review a speed limit.

The traffic state can be acquired by measurement, but in a predetermined road where the traffic state cannot be measured, an estimated value is often obtained using measurement values of surrounding roads. For example, it has been proposed, in a certain city, to estimate traffic volume on a road in the city using traffic volume measured at a camera installation point and a travel route of an automobile estimated from global positioning system (GPS) data of a taxi and a mobile phone (Non Patent Literature 1). In addition, it has been proposed that, in an urban area, a road is regarded as a network including a link and a node, and travel speed of an automobile on the link is estimated using travel speed of the automobile obtained from information of a roadside device or a camera installed at a main intersection or a highway (Non Patent Literature 2). Furthermore, it has been proposed that a region is divided into small cells, and traffic density is estimated using traffic density measured in some cells by using communication between roadside devices and vehicles (Non Patent Literature 3). According to these, a traffic state of a predetermined road where the traffic state cannot be measured is estimated by utilizing measurement on surrounding roads.

### CITATION LIST

### Non Patent Literature

Non Patent Literature 1: P. Wang, J. Lai, Z. Huang, Q. Tan and T. Lin, “Estimating Traffic Flow in Large Road Networks Based on Multi-Source Traffic Data,” in IEEE Transactions on Intelligent Transportation Systems, vol. 22, no. 9, pp. 5672-5683, 2021.
Non Patent Literature 2: Y.-K. Ki, J.-W. Choi, H.-J. Joun, G.-H. Ahn and K.-C. Cho, “Real-time estimation of travel speed using urban traffic information system and CCTV,” 2017 International Conference on Systems, Signals and Image Processing (IWSSIP), Poznan, Poland, pp. 1-5, 2017.
Non Patent Literature 3: C. S. Shin, J. Lee and H. Lee, “Infrastructure-Less Vehicle Traffic Density Estimation via Distributed Packet Probing in V2V Network,” in IEEE Transactions on Vehicular Technology, vol. 69, no. 10, pp. 10403-10418, 2020.

### SUMMARY OF INVENTION

### Technical Problem

However, it is not always possible to measure a traffic state on surrounding roads of a predetermined road, and all measurement values necessary for estimation may not be obtained. In this case, there is a problem that it is difficult to estimate a traffic state of a predetermined road where a traffic state cannot be measured.

The present disclosure has been made in view of the above circumstances, and an object thereof is to facilitate estimation of a traffic state of a predetermined road where a traffic state cannot be measured.

### Solution to Problem

In order to achieve the above object, an invention according to claim 1 is a learned model for causing a computer to function to estimate a distribution of traffic parameters and output an estimated distribution on the basis of road information that is physical information of a road, the learned model inputting road information regarding a predetermined road and outputting an estimated distribution of predetermined traffic parameters.

### Advantageous Effects of Invention

As described above, according to the present disclosure, it is possible to easily estimate a traffic state of a predetermined road on which the traffic state cannot be measured.

### BRIEF DESCRIPTION OF DRAWINGS

FIG. 1 is an overall configuration diagram of a communication system according to an embodiment.

FIG. 2 is an electrical hardware configuration diagram of a traffic state estimation device according to the embodiment.

FIG. 3 is an electrical hardware configuration diagram of a database server according to the embodiment.

FIG. 4 is a functional configuration diagram of the traffic state estimation device in a learning phase.

FIG. 5 is a diagram illustrating a state in which a distribution p_{θ}(k) of traffic parameters is created from a numerical string Kₙ of traffic parameters.

FIG. 6 is a functional configuration diagram of the traffic state estimation device in an estimation phase.

FIG. 7 is a diagram illustrating an example in which a predetermined estimated value regarding a traffic parameter is derived in a case where a 99% value of an estimated distribution is set as a maximum value.

FIG. 8 is a flowchart illustrating processing executed by the traffic state estimation device in the learning phase.

FIG. 9 is a flowchart illustrating processing executed by the traffic state estimation device in the estimation phase.

FIG. 10 is a diagram illustrating each feature amount of road information.

FIG. 11 is a diagram illustrating an average and a standard deviation of a loss obtained using evaluation data in each set of data, a root mean square error (RMSE) of an average value of traffic density, and an RMSE of a maximum value thereof.

FIG. 12 is a diagram illustrating an example of data for which Loss can be estimated to be 0.1 or less among 2000 pieces of evaluation data in data set 1.

### DESCRIPTION OF EMBODIMENTS

Hereinafter, embodiments of the present invention will be described with reference to the drawings.

### [System Configuration of Embodiment]

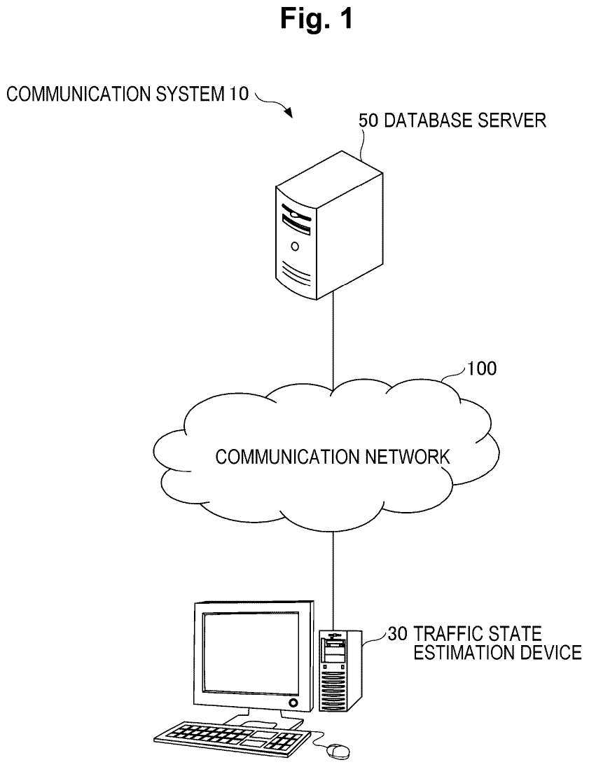

First, an overall configuration of a communication system according to an embodiment will be described with reference to FIG. 1. FIG. 1 is an overall configuration diagram of the communication system according to the embodiment.

As illustrated in FIG. 1, a communication system 10 of the present embodiment is constructed by a traffic state estimation device 30 and a database server 50. The traffic state estimation device 30 and the database server 50 can communicate via a communication network 100 such as a local area network (LAN) or the Internet.

The communication network 100 may include a dedicated network such as an Internet Service Provider (ISP) network managed and (or) operated by a communication carrier. A connection form of the communication network 100 may be either wireless or wired.

The traffic state estimation device 30 includes one or a plurality of computers. When the traffic state estimation device 30 includes a plurality of computers, it may be referred to as a “traffic state estimation device” or a “traffic state estimation system”.

The traffic state estimation device 30 includes a learning engine and an estimation engine for machine learning.

The traffic state estimation device 30 can estimate “traffic volume”, “travel speed”, or “traffic density” which is a component of a “traffic state” of a predetermined road where a traffic state cannot be measured (estimation target road). In the present embodiment, data indicating a value of each component of the traffic state is expressed as a “traffic parameter”.

By adapting the present embodiment to each of the three types of traffic parameters, it is possible to estimate three. The traffic state estimation device 30 includes a machine learning model 90a that inputs road information acquired from the database server 50 and outputs a distribution of traffic parameters. The traffic state estimation device 30 uses data of the predetermined road on which the traffic parameters are measured to learn the machine learning model 90a.

The “road information” is physical information of roads that are relatively easily available, and is, for example, detailed information such as a road state survey obtained by a national road or street traffic situation survey in Japan, or detailed information of roads shown in a road ledger or the like that is easily available from a government office or the like. Specific examples thereof include area information, a road type, the number of lanes of a road, a lane width of a road, and a road extension. The “area information” is information regarding an area such as a prefecture, a municipality, or the like to which a road belongs. The “road type” is information related to a type of a road such as a national expressway, a national road, or a general prefectural road. Note that the “road extension” is a length of a route designated or certified based on the provisions of the Road Act of Japan and the like.

By constructing a learned machine learning model 90b, the traffic state estimation device 30 can estimate a distribution of traffic parameters from road information even for a road on which traffic parameters are not measured. Furthermore, after estimating the distribution of the traffic parameters, the traffic state estimation device 30 can acquire estimated values such as a maximum value and a mode of the traffic parameters from the distribution.

The database server 50 stores road information and traffic parameters.

The traffic state estimation device 30 causes the machine learning model 90a to learn a relationship between the road information and the distribution of the traffic parameters by the learning engine. By the estimation engine, the traffic state estimation device 30 inputs the road information to the learned machine learning model 90b by the learning engine to output the distribution of the traffic parameters, and further derives estimated values such as the maximum value and the mode of the traffic parameters.

### [Hardware Configuration]

### <Hardware Configuration of Traffic State Estimation Device>

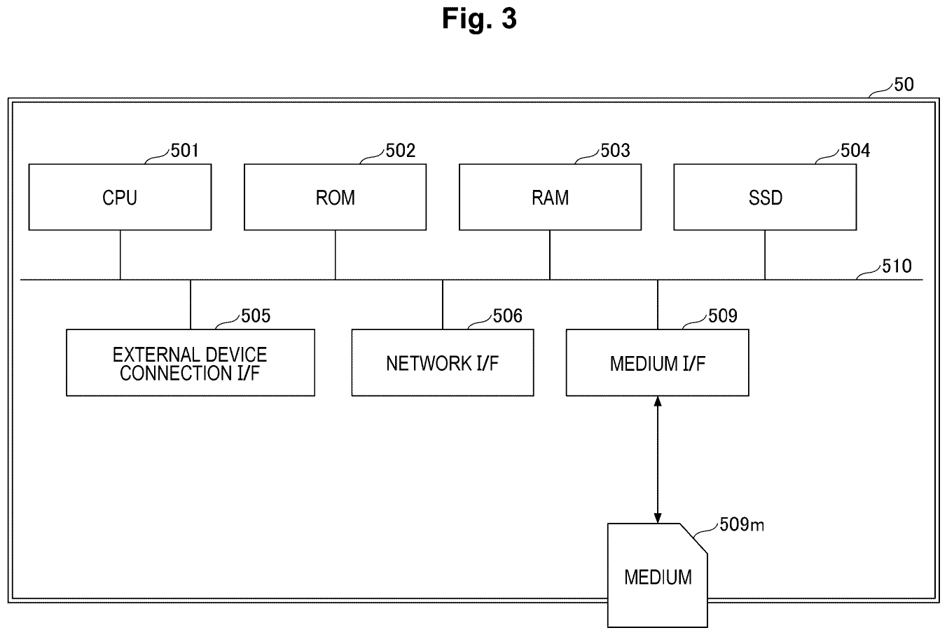

Next, an electrical hardware configuration of the traffic state estimation device 30 will be described with reference to FIG. 3. FIG. 3 is an electrical hardware configuration diagram of the traffic state estimation device.

As illustrated in FIG. 3, the traffic state estimation device 30 includes, as a computer, a CPU 301, a ROM 302, a RAM 303, an SSD 304, an external device connection interface (I/F) 305, a network I/F 306, a display 307, an operation unit 308, a medium I/F 309, and a bus line 510.

Among them, the CPU 301 controls an operation of the entire traffic state estimation device 30. The ROM 302 stores a program used for driving the CPU 301, such as an IPL. The RAM 303 is used as a working area of the CPU 301.

The SSD 304 reads or writes various types of data under control of the CPU 301. Note that, a hard disk drive (HDD) may be used instead of the SSD 304.

The external device connection I/F 305 is an interface for connecting various types of external devices. Examples of the external devices in this case include a display, a speaker, a keyboard, a mouse, a USB memory, and a printer.

The network I/F 306 is an interface for performing data communication via the communication network 100.

The display 307 is a type of display means such as a liquid crystal or an organic electro luminescence (EL) that displays various images.

The operation unit 308 is a keyboard, a pointing device, or the like, and is an example of input means for receiving an input operation of a character, a numerical value, various instructions, or the like.

The medium I/F 309 controls reading or writing (storing) of data with respect to a recording medium 309m such as a flash memory. The recording medium 309m also includes a DVD, a Blu-ray Disc (registered trademark), and the like.

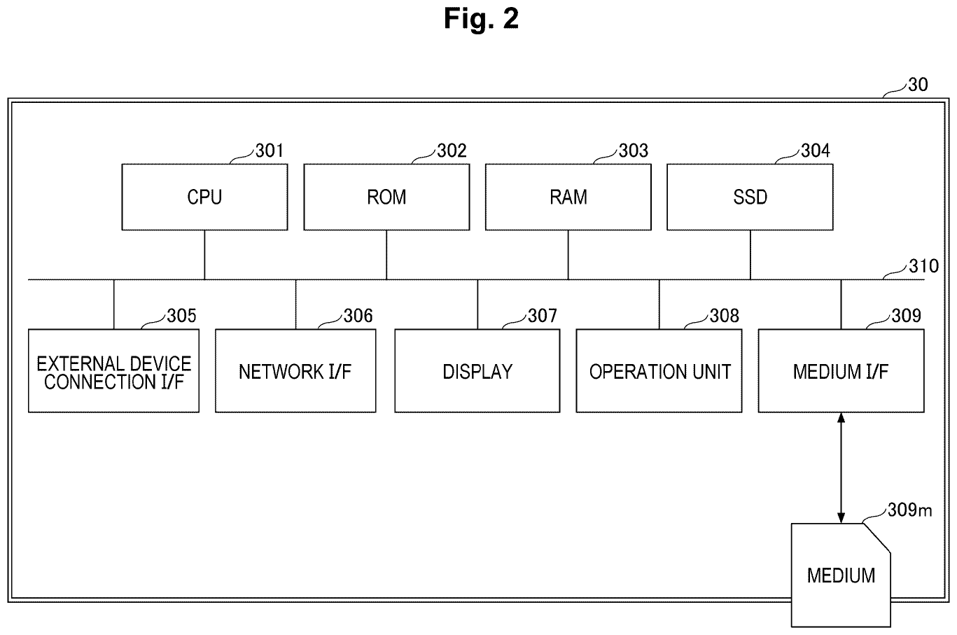

The bus line 310 is an address bus, a data bus, or the like for electrically connecting the components such as the CPU 301 illustrated in FIG. 2.

### <Hardware Configuration of Database Server>

Next, an electrical hardware configuration of the database server 50 will be described with reference to FIG. 3. FIG. 3 is an electrical hardware configuration diagram of the database server.

As illustrated in FIG. 3, the database server 50 includes a central processing unit (CPU) 501, a read only memory (ROM) 502, a random access memory (RAM) 503, a solid state drive (SSD) 504, an external device connection interface (I/F) 505, a network I/F 506, a medium I/F 509, and a bus line 510.

Among them, the CPU 501 controls an operation of the entire database server 50. The ROM 502 stores a program used for driving the CPU 501, such as an initial program loader (IPL). The RAM 503 is used as a work area of the CPU 501.

The SSD 504 reads or writes various types of data under control of the CPU 501. Note that, a hard disk drive (HDD) may be used instead of the SSD 504.

The external device connection I/F 505 is an interface for connecting various types of external devices. Examples of the external device in this case include a display, a speaker, a keyboard, a mouse, a universal serial bus (USB) memory, and a printer.

The network I/F 506 is an interface for performing data communication via the communication network 100.

The medium I/F 509 controls reading or writing (storing) of data with respect to a recording medium 509m such as a flash memory. The recording medium 509m also includes a digital versatile disc (DVD), a Blu-ray Disc (registered trademark), and the like.

The bus line 510 is an address bus, a data bus, or the like for electrically connecting the components such as the CPU 501 illustrated in FIG. 3.

### [Data Stored in Database Server]

Next, an example of data stored in the database server 50 will be described.

The database server 50 stores matrices A and Aₜₑₛₜ indicating road information and a matrix K indicating traffic parameters. The matrix A indicating the road information is A=[a₁, a₂, . . . , a_{N}]^{T}. Note that T represents a transposed matrix.

aₙ (n=1, 2, . . . , N) is a numerical string of a feature amount of a road n, and is expressed as an=[a_{n, 1}, a_{n, 2}, . . . , a_{n, M}]^{T}.

a_{n, m} (m=1, 2, . . . , M) is a numerical value of a feature amount m of the road n. As the feature amount, for example, a feature amount 1 is the number of lanes, and a feature amount 2 is a road extension or the like.

The matrix Aₜₑₛₜ indicating the road information is a matrix of road information used for input of an estimation phase. The matrix K of traffic parameters is K=[k₁, k₂, . . . , k_{N}]^{T}. kₙ (n=1, 2, . . . , N) is a numerical string of the traffic parameters of the road n and is expressed as follows.

$$\begin{matrix}[ Math . 1 ] & \\ {k}_{n} = {[ {k}_{n , 0} , {k}_{n , 1} , … , {k}_{n , τ} ]}^{T} & \end{matrix}$$

$$Further ,$$

$$\begin{matrix}[ Math . 2 ] & \\ {k}_{n , t} ( t = 0 , 1 , … , τ ) & \end{matrix}$$

is a numerical value of the traffic parameter at time t.

### [Functional Configuration of Traffic State Estimation Device]

Next, a functional configuration in a learning phase realized by a learning engine of the traffic state estimation device 30 and a functional configuration in an estimation phase realized by an estimation (inference) engine thereof will be described.

### <Functional Configuration in Learning Phase>

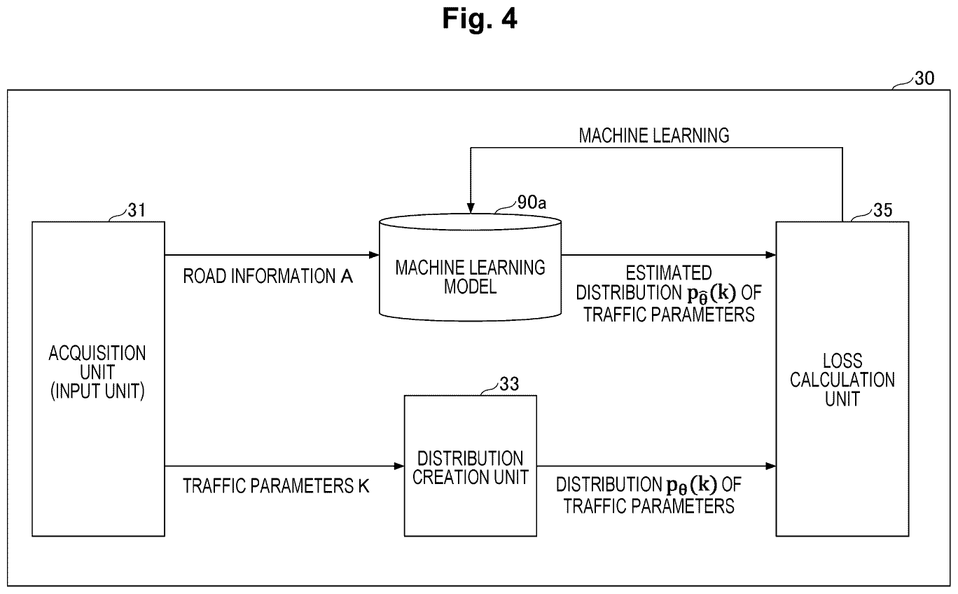

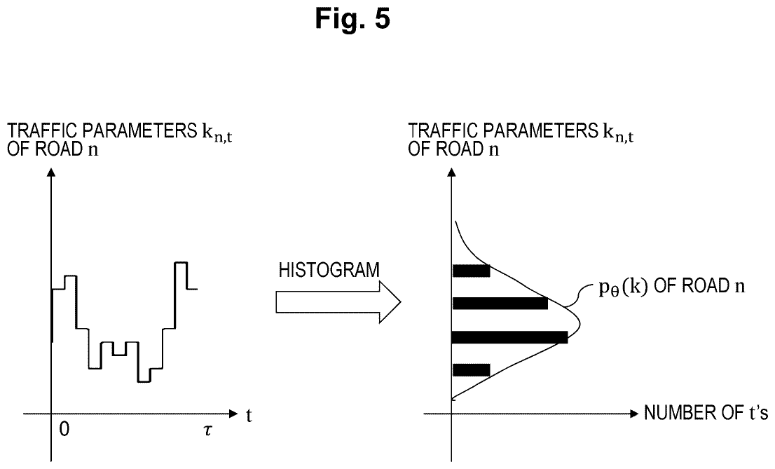

FIG. 4 is a functional configuration diagram of the traffic state estimation device in the learning phase. FIG. 5 is a diagram illustrating a state in which a distribution pe (k) of traffic parameters is created from the numerical string Kₙ of the traffic parameters. Note that the traffic state estimation device 30 uses a fully connected neural network for machine learning.

As illustrated in FIG. 4, the traffic state estimation device 30 includes an acquisition unit 31, a distribution creation unit 33, and a loss calculation unit 35. Each of the units is a function implemented by a command from the CPU 301 in FIG. 2, on the basis of a program. In addition, the machine learning model 90a is stored in the RAM 303 or the SSD 304.

The acquisition unit 31 acquires a matrix A of road information and a matrix K of traffic parameters from the database server 50. Note that the acquisition unit 31 may acquire the matrix A of the road information and the matrix K of the traffic parameters not from the database server 50 but by a user's input operation.

The acquisition unit 31 also serves as an input unit that inputs the matrix A of the road information as input data to the machine learning model 90a. As a result, the machine learning model 90a outputs an estimated distribution p_{θ\hat{ }}(k) of the traffic parameters. Note that there is a relationship described below in the present specification due to restriction of characters that can be used in the specification.

$$\begin{matrix}[ Math . 3 ] & \\ \hat{θ} = θ \hat{} & \end{matrix}$$

As illustrated in FIG. 5, the distribution creation unit 33 creates a distribution pe (k) of traffic parameters for each road n (n=1, 2, . . . , N) by approximating a histogram of traffic parameters created based on a numerical string kₙ of traffic parameters of each road n (n=1, 2, . . . , N) input from the acquisition unit 31 with a probability distribution. Examples of the probability distribution include a normal distribution N(x; μ, σ²), an exponential distribution Exp(x; λ), a gamma distribution Gamma (x; α, β), and the like.

The loss calculation unit 35 calculates a loss (Loss) between the distribution p_{θ}(k) of the traffic parameters created by the distribution creation unit 33 and the estimated distribution p_{θ\hat{ }}(k) of the traffic parameters output from the machine learning model 90a, and executes machine learning on the machine learning model 90a. The loss calculation unit 35 calculates the loss by divergence illustrated in (Equation 1).

$$\begin{matrix}[ Math . 4 ] & \\ Loss = \int {p}_{θ} ( k ) log \frac{{p}_{θ} ( k )}{{p}_{\hat{θ}} ( k )} & ( Equation 1 )\end{matrix}$$

This (Equation 1) represents a distance between the two distributions. The machine learning model 90a learns to reduce the loss.

### <Functional Configuration in Estimation Phase>

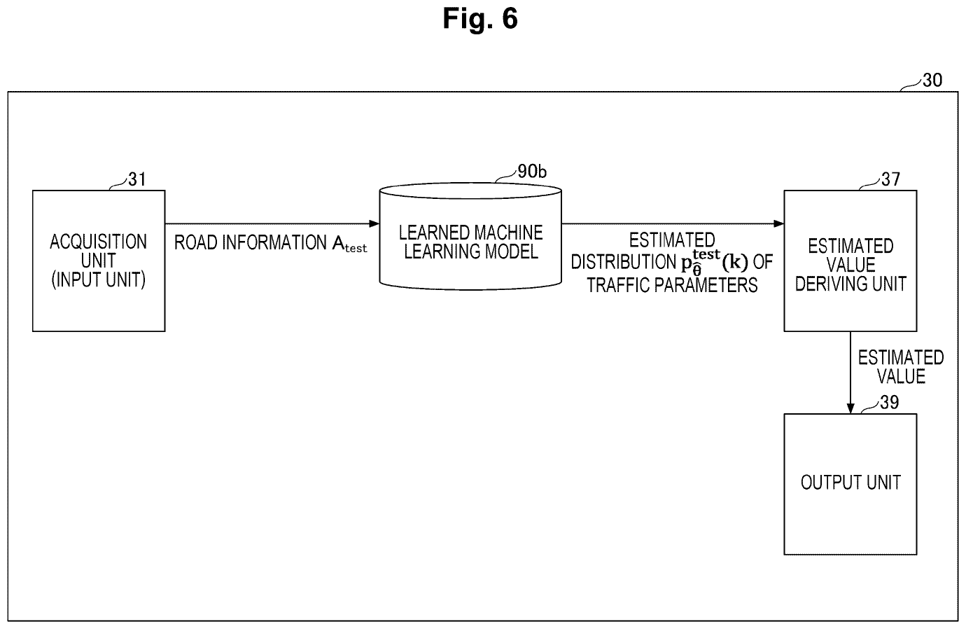

FIG. 6 is a functional configuration diagram of the traffic state estimation device in an estimation phase.

As illustrated in FIG. 6, the traffic state estimation device 30 includes the acquisition unit 31, an estimated value deriving unit 37, and an output unit 39. Each of the units is a function implemented by a command from the CPU 301 in FIG. 2, on the basis of a program. In addition, the learned machine learning model 90b learned in the learning phase is stored in the RAM 303 or the SSD 304.

The acquisition unit 31 acquires a matrix Aₜₑₛₜ of road information from the database server 50. Note that the acquisition unit 31 may acquire the matrix Aₜₑₛₜ of the road information not from the database server 50 but by a user's input operation.

The acquisition unit 31 also serves as an input unit that inputs the matrix Aₜₑₛₜ of the road information as input data to the learned machine learning model 90b. As a result, the learned machine learning model 90b outputs an estimated distribution p_{θ\vec{ }}^{test}(k) of traffic parameters.

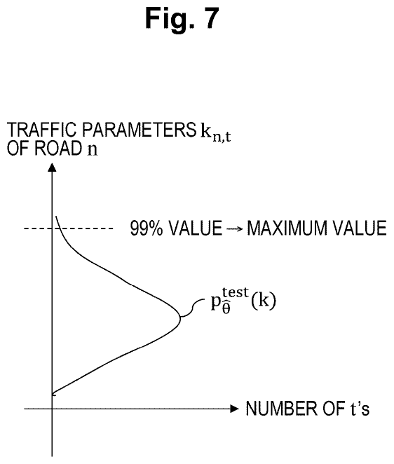

The estimated value deriving unit 37 derives a predetermined estimated value regarding a traffic parameter based on the estimated distribution p_{θ\vec{ }}^{test}(k) of the traffic parameters output from the learned machine learning model 90b. FIG. 7 is a diagram illustrating an example in which a predetermined estimated value regarding a traffic parameter is derived in a case where a 99% value of an estimated distribution is set as a maximum value. For example, as illustrated in FIG. 7, the estimated value deriving unit 37 derives the estimated value regarding the traffic parameter by using a percentage value of the estimated distribution of the traffic parameters. FIG. 7 illustrates a case where the 99% value is set as the maximum value, but a 1% value may be set as a minimum value. Furthermore, the estimated value deriving unit 37 may derive an average value or a mode of the estimated distribution of the traffic parameters as the predetermined estimated value regarding the traffic parameter. Each estimated value represents a traffic state (traffic volume, travel speed, or traffic density) related to the predetermined road.

The output unit 39 outputs the predetermined estimated value derived by the estimated value deriving unit 37 from the traffic state estimation device 30. Examples of the output include a case where the output is displayed on a display connected to the external device connection I/F 305 of FIG. 2, and a case where the output is transmitted to an external device such as another personal computer (PC) or a printer via the network I/F 306.

### [Processing or Operation of Traffic State Estimation Device]

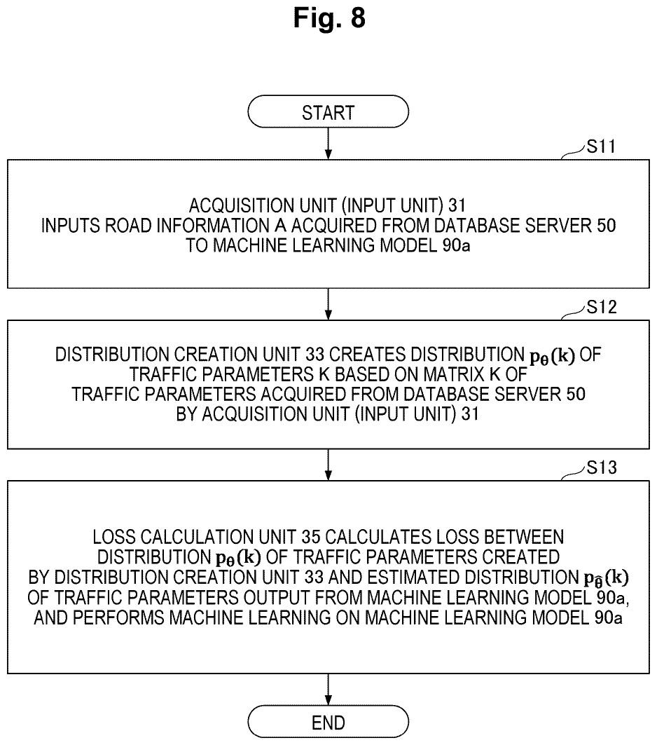

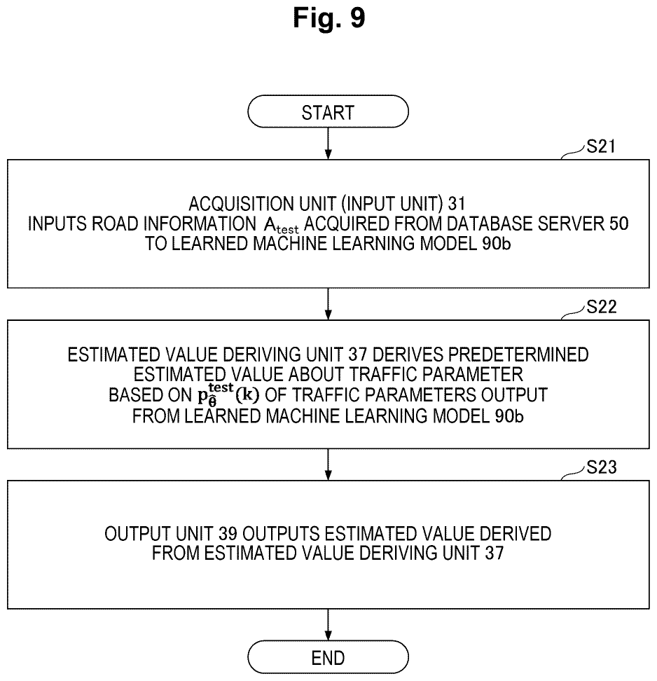

Subsequently, processing or operation in the learning phase and the estimation phase of the traffic state estimation device 30 will be described with reference to FIGS. 8 and 9.

### <Processing or Operation in Learning Phase>

FIG. 8 is a flowchart illustrating processing or operation executed by the traffic state estimation device in the learning phase.

S11: The acquisition unit (input unit) 31 inputs road information A acquired from the database server 50 to the machine learning model 90a.

S12: The distribution creation unit 33 creates a distribution of the traffic parameters K based on the matrix K of the traffic parameters acquired from the database server 50 by the acquisition unit (input unit) 31.

S13: The loss calculation unit 35 calculates a loss between the distribution pe (k) of the traffic parameters K created by the distribution creation unit 33 and the estimated distribution pe (k) of the traffic parameters output from the machine learning model 90a, and executes machine learning on the machine learning model 90a.

The traffic state estimation device 30 completes the machine learning of the machine learning model 90a by repeating steps S11 to S13 described above.

### <Processing or Operation in Estimation Phase>

FIG. 9 is a flowchart illustrating processing or operation executed by the traffic state estimation device in the estimation phase.

S21: The acquisition unit (input unit) 31 inputs road information Aₜₑₛₜ acquired from the database server 50 to the learned machine learning model 90b.

S22: The estimated value deriving unit 37 derives a predetermined estimated value based on the estimated distribution pe test (k) of the traffic parameters output from the learned machine learning model 90b.

S23: The output unit 39 outputs the predetermined estimated value derived by the estimated value deriving unit 37.

### [Contents of Experiment]

Subsequently, since an experiment for estimating a distribution of traffic density among a traffic state has been performed, contents thereof will be described.

### <Used Data>

For the experiment, data of a national road or street traffic situation survey in 2010, 2015, and 2021 was used. This data describes three survey results of road information, traffic volume, and travel speed, which were surveyed on one weekday in September to November, for all routes of expressways, national roads, and prefectural roads and some of city roads throughout Japan. Regarding the traffic volume, the traffic volume for each hour for 12 hours from 7:00 to 19:00 or 24 hours is described for each inbound and outbound direction. Regarding the travel speed, average travel speed during congestion (7:00 to 9:00, 17:00 to 19:00) and during daytime non-congestion (9:00 to 17:00) are described for each inbound and outbound direction.

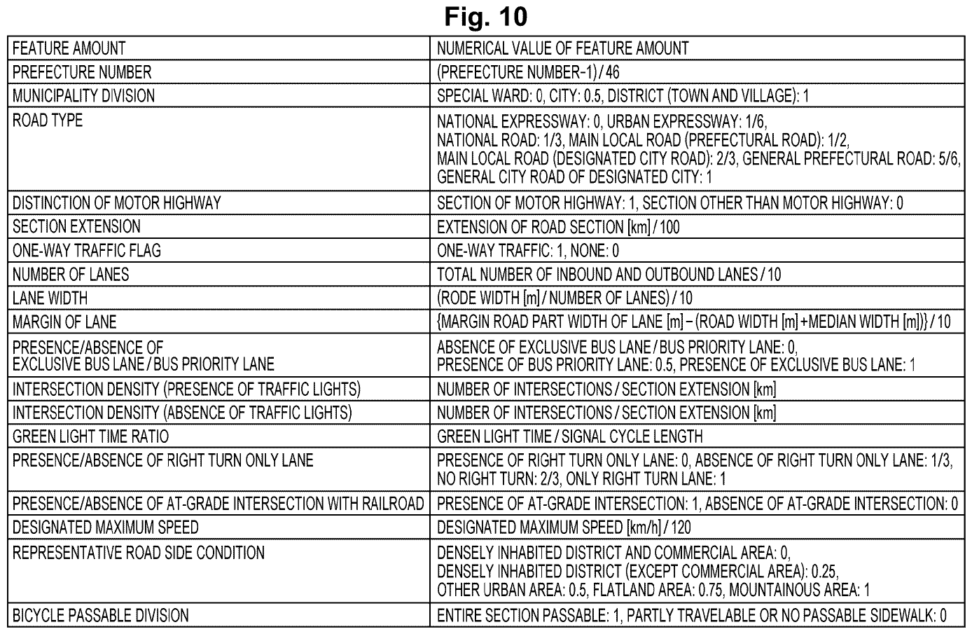

In the experiment, items illustrated in FIG. 10 were used as a feature amount of the road information. Roads having the same feature amount of road information are regarded as the same road, and in the experiment, a road in which survey results are described in all three years of 2010, 2015, and 2021 was used.

Regarding a traffic parameter used in the experiment, in each of the inbound and outbound directions of each road, a traffic density per hour from 7:00 to 19:00 is calculated by dividing a traffic volume per hour from 9:00 to 17:00 by average travel speed during daytime non-congestion (9:00 to 17:00) and by dividing a traffic volume per hour from 7:00 to 9:00 and from 17:00 to 19:00 by average travel speed during congestion (7:00 to 9:00, 17:00 to 19:00), and a traffic density of the road obtained by adding an inbound traffic density and an outbound traffic density during each time is used as the traffic parameter. Note that, in the used data, there is a case where only data for 12 hours from 7:00 to 19:00 of the traffic volume exists, and only the average speed calculated from the data of 7:00 to 19:00 is described regarding the travel speed. Therefore, only the traffic density of 7:00 to 19:00 is used in this experiment. In addition, since data for three years is used, there is a plurality of traffic densities of 7:00 to 19:00 for one road. For example, the traffic density in one year is 1.38 vehicles/km at 7:00, 1.52 vehicles/km at 8:00, . . . and 2.17 vehicles/km at 19:00, and the traffic density in another year is 1.30 vehicles/km at 7:00, 1.49 vehicles/km at 8:00, . . . and 2.04 vehicles/km at 19:00. However, a numerical string of the traffic parameters of the road was created using all the traffic densities from 7 to 19:00 for one road. For example, it was assumed to be [1.38, 1.52, . . . , 2.17, 1.30, 1.49, . . . 2.04, . . . ].

The traffic density was pre-calculated on each road and data unsuitable for use was screened. Specifically, since a light automobile having the smallest size in a passenger car has a total length of about 3.4 m, the number of automobiles that can exist in 1 km is about 1000 [m]/3.4 [m]≈294 at most. However, when the traffic density was calculated from the traffic volume and the speed, there was a case where the average traffic density exceeded 294 [vehicles/km] on a road with a large traffic volume and a slow speed, and therefore data of the road was not used. The data remaining after scraping was data of 21317 roads. The data of 2000 roads was used as verification data, and the data of the remaining 19317 roads was used for the experiment.

### <Setting of Learning Phase>

For machine learning used in the learning phase (full connect neural network), parameter tuning of hyperparameters was tried 50 times by an automatic optimization framework (for example, Optuna developed by Preferred Networks, Inc., Japan) of predetermined hyperparameters using the verification data in advance, and were determined as follows.
Number of intermediate layers: 4 (selected from 1, 2, 3, 4, 5)
Dimension of intermediate layer: [15, 30, 25, 25] (selected from 5, 10, . . . , 40 each)
Number of epochs: 160 (selected from 20, 40, . . . 200)
Batch size: 32 (selected from 32, 64, 128, 256, 512)
Learning rate: 1.08×10⁻³ (selected from 10⁻⁵ to 10⁻¹)
Dropout: 0.2 (selected from 0.1, 0.2, 0.3, 0.4, 0.5)
Activation function: ReLu function (selected from Linear function, ReLu function, Sigmoid function, LeakyReLu function, tanh function)

A probability distribution used by the distribution creation unit to create a distribution of traffic parameters is a normal distribution.

### Experiment Results

In the experiment, a loss after machine learning was evaluated. Among data of 19317 roads used in the experiment, data of 2000 roads was used as evaluation data, and data of the remaining 17317 roads was used as learning data. Note that three sets of evaluation data and learning data were created by changing a way of data division.

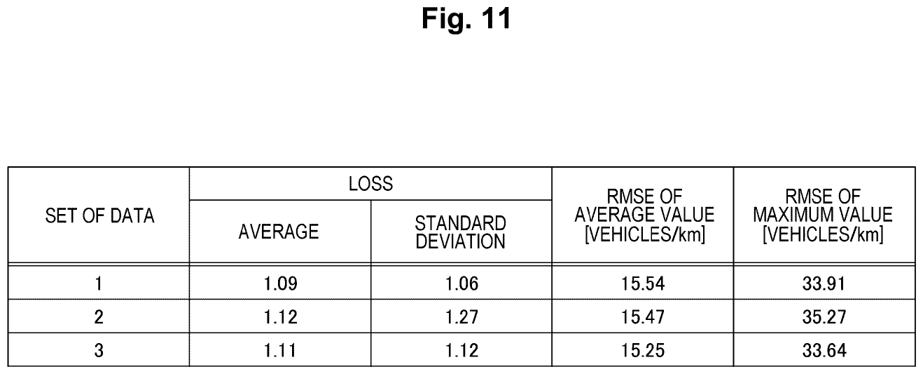

For each set of data, learning of the machine learning model using the learning data and calculation of a loss (Loss represented by the above (Equation 1)) in the learned machine learning model using the evaluation data were executed five times. FIG. 11 illustrates an average and a standard deviation of the loss obtained using the evaluation data in each set of data, a root-mean-square error (RMSE) of an average value of traffic density, and an RMSE of a maximum value thereof. Note that an estimated value of the maximum value of the traffic density is a 99% value of an estimated distribution of traffic parameters. The experiment has shown that the loss is suppressed to 1.2 or less on average, the RMSE of the average value is suppressed to 16 vehicles/km or less, and the RMSE of the maximum value is suppressed to 36 vehicles/km or less.

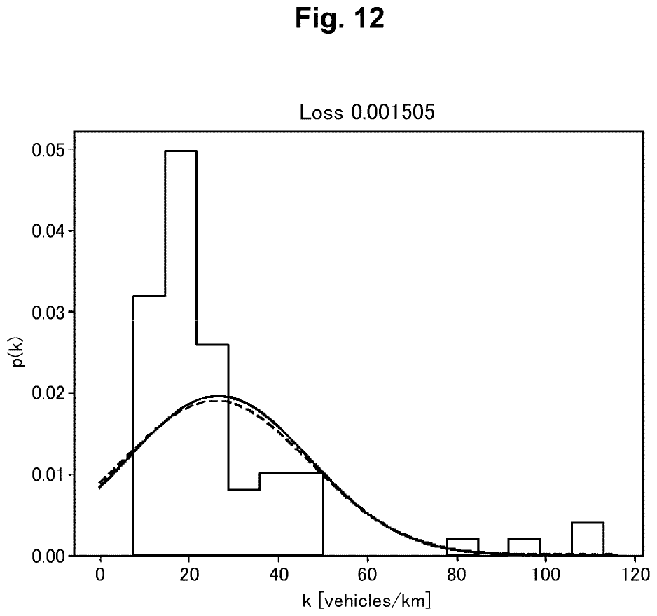

In addition, FIG. 12 illustrates a graph of a distribution p_{θ}(k) of traffic parameters and an estimated distribution p_{θ\vec{ }}(k) of traffic parameters as an example of data in which Loss can be estimated to be 0.1 or less among 2000 pieces of evaluation data in data set 1. In the graph of FIG. 12, the horizontal axis represents a traffic density k [vehicles/km], and the vertical axis represents a distribution value p(k). In addition, in FIG. 12, a solid line represents the distribution p_{θ}(k) of the traffic parameters, a dotted line represents the estimated distribution p_{θ\hat{ }}(k) of the traffic parameters, and a bar graph represents a histogram used when creating the distribution of the traffic parameters. Note that the bar graph illustrated in FIG. 12 corresponds to the bar graph illustrated in FIG. 5. Further, the dotted line illustrated in FIG. 12 corresponds to the curve graph illustrated in FIG. 7. Specifically, FIG. 12 illustrates a graph of the distribution p_{θ}(k) and the estimated distribution p_{θ\hat{ }}(k) of the traffic parameters that can be estimated by Loss=0.001505.

As illustrated in FIG. 12, when the distribution of the traffic parameters and the estimated distribution of the traffic parameters are superimposed on one drawing, it can be confirmed that a true value and an estimated value output by the learning model of the present embodiment are values that are as close as possible. As described above, it is considered that Loss can be estimated to be small by the present embodiment on a road where the traffic density is low in a lot of time and the traffic density is high in a part of time.

### Main Effects of Embodiment

As described above, according to the present embodiment, it is possible to easily estimate a traffic state of a predetermined road on which the traffic state cannot be measured. Specifically, it is as follows.

(1) A distribution of traffic parameters can be estimated for various roads from which road information is obtained. In addition, an estimated value such as a maximum value or an average value can be obtained using the distribution of the traffic parameters.

(2) The present disclosure can be used, for example, in a communication base station design in consideration of communication services for automobiles. In the communication base station design, it has been studied to design in consideration of a communication traffic amount generated from the communication services for automobiles in preparation for a rapid increase in the communication traffic amount due to the spread of the services. The communication services for automobiles include remote monitoring of automatic driving without a driver (Reference Literature 1), streaming of in-vehicle entertainment such as music and video (Reference Literature 2), Wi-Fi in the vehicle (Reference Literature 3), and the like. The communication base station is designed with reference to a prediction value of a maximum communication traffic amount in a design target region. It is considered that the maximum communication traffic amount generated from the communication services for automobiles is predicted using a “maximum value of traffic density”. Therefore, by using the technology of the present disclosure, it is possible to acquire an approximate maximum value of the traffic density by estimating a maximum value of the traffic density, estimating a maximum value of traffic volume, a minimum value or an average value of speed, or the like for various roads. Therefore, the maximum communication traffic amount generated from the communication services for automobiles can be predicted in any region, and the communication base station can be designed before the spread of the services.
<Reference Literature 1> Ministry of Economy, Trade and Industry, “Panel on Business Strategies for Automated Driving “Action Plan for Realizing Automated Driving” Version 5.0-Toward social implementation of Level 4 automated driving service-Report Outline”
(https://www.meti.go.jp/shingikai/mono_info_service/jido_soko/pdf/20210430_02.pdf) [Published on April 30, 2021]
<Reference Literature 2>NTT DOCOMO, “DOCOMO and BMW launch Japan's first 5G and consumer eSIM compatible connected car service”
(https://www.docomo.ne.jp/info/news_release/2022/03/01_01.html) [Published on Mar. 1, 2022]
<Reference Literature 3>NTT DOCOMO, “docomo in Car Connect”
(https://www.docomo.ne.jp/service/in_car_connect/) [Viewed in February 2023]

### Supplement

The present invention is not limited to the embodiment described above, and for example, may be configured or processed (operated) as follows.

(1) Although the traffic state estimation device 30 can also be realized by a computer and a program, this program can also be recorded in a (non-transitory) recording medium or provided via the communication network 100 such as the Internet.

(2) Each of the CPUs 301, 501 as a processor which is hardware may be a single CPU or a plurality of CPUs.

### Relationship with Basic Application

The present patent application claims the priority based on International Patent Application PCT/JP2023/012929 filed on Mar. 29, 2023, and the entire contents of International Patent Application PCT/JP2023/012929 are incorporated herein by reference.

### REFERENCE SIGNS LIST

10 Communication system
30 Traffic state estimation device
50 Database server
90a Machine learning model
90b Learned machine learning model (also referred to as “learned model”)
31 Acquisition unit (input unit)
33 Distribution creation unit
35 Loss calculation unit
37 Estimated value deriving unit
39 Output unit

1. (canceled)

2. (canceled)

3. (canceled)

4. (canceled)

5. A traffic state estimation device configured to estimate a traffic states of roads, the traffic state estimation device comprising:
a trained model configured to:
estimate one or more distributions of first traffic parameters indicating values of components of the traffic states, based on first road information that is physical information of the roads, and
output the distributions; and
circuitry configured to:
input, to the trained model, second road information related to a predetermined road, such that the trained model outputs a first distribution of second traffic parameters in association with the second road information, and
derive an estimate value regarding the second traffic parameters, based on the first distribution of the second traffic parameters output from the trained model.

6. The traffic state estimation device according to claim 5, wherein the estimate value is a value derived using a percentile value of the first distribution, or, an average value or a mode of the first distribution.

7. A non-transitory computer readable storage medium storing a program configured to cause a computer to execute a method, the method comprising:
inputting, to a trained model that:
estimates one or more distributions of first traffic parameters indicating values of components of traffic states, based on first road information that is physical information of roads, and
outputs the distributions,
second road information related to a predetermined road such that the trained model outputs a first distribution of second traffic parameters in association with the second road information; and
deriving an estimate value regarding the second traffic parameters based on the first distribution of the second traffic parameters output from the trained model.

8. The traffic state estimation device according to claim 5, wherein the trained model is a model configured to learn a relationship between the first road information and the first traffic parameters, and a relationship between the second road information and the second traffic parameters.

9. The traffic state estimation device according to claim 5, wherein the second road information indicates area information indicating an area to which the predetermined road belongs, a road type of the predetermined road, the number of lanes of the predetermined road, a lane width of the predetermined road, or a road extension of the predetermined road.

10. The traffic state estimation device according to claim 5, wherein the first traffic parameters and the second traffic parameters are data indicating traffic volume, a travel speed, or traffic density.
